(19) United States
(12) Patent Application Publication
(10) Pub. No.: US 2009/0057780 A1
(43) Pub. Date: Mar. 5, 2009

(54) FINFET STRUCTURE INCLUDING MULTIPLE SEMICONDUCTOR FIN CHANNEL HEIGHTS

(75) Inventors: Robert C. Wong, Poughkeepsie, NY (US); Haining Yang, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/845,265

(22) Filed: Aug. 27, 2007

(51) Int. Cl. H01L 27/12; H01L 21/336; H01L 29/76

(52) U.S. Cl. 257/401; 257/347; 438/156; 257/E27.112; 257/E21.409

(57) ABSTRACT

A semiconductor structure and a method for fabricating the semiconductor structure include a first semiconductor fin and a second semiconductor fin of the same overall height over a substrate. Due to the presence of a channel stop layer at the base of one of the first semiconductor fin and the second semiconductor fin, but not the other of the first semiconductor fin and the second semiconductor fin, the first semiconductor fin and the second semiconductor fin have different channel heights. The semiconductor fins may be used to fabricating a corresponding first finFET and a corresponding second finFET with differing performance characteristics due to the different channel heights of the first semiconductor fin and the second semiconductor fin.

### BACKGROUND

1. Field of the Invention

The invention relates generally to finFET structures within semiconductor structures. More particularly, the invention relates to enhanced performance finFET structures within semiconductor structures.

2. Description of the Related Art

Semiconductor structures include semiconductor devices that are located and fabricated within and/or upon a semiconductor substrate. Such semiconductor devices typically include transistors and diodes. Also optionally included are additional devices, which need not necessarily be semiconductor devices, such as resistors and capacitors. Transistors, including in particular field effect transistors, are generally common semiconductor devices that are used within semiconductor circuits. More particularly, planar field effect transistors have been extensively used, dimensionally scaled and incrementally improved for several decades.

As semiconductor technology continues to advance and semiconductor device and structure dimensions continue to decrease, a recently evolving trend within semiconductor device and structure fabrication has been the advent of the finFET device, rather than planar field effect transistor device. A finFET device is characterized by a semiconductor fin that is positioned perpendicularly with respect to a semiconductor substrate, to provide a vertical channel within the finFET device. This vertical channel, rather than an exclusively planar channel that is present within a planar field effect transistor device, is covered with a gate dielectric, and subsequently also with a gate electrode.

While finFET devices certainly provide an advantage in comparison with planar field effect transistor devices within the context of an aerial dimensional scaling, finFET devices are nonetheless not entirely without problems within the semiconductor fabrication art. In particular, while finFET devices provide for reduced aerial dimensions, finFET devices often achieve that result absent any flexibility in channel dimensions.

Various field effect transistor devices and structures having desirable properties, including finFET devices and structures having desirable properties, are known in the semiconductor fabrication art.

For example, Aller et al., in U.S. Pat. No. 6,909,147, teaches a finFET structure that includes multiple semiconductor fins having multiple heights. The semiconductor fins having the multiple heights are formed using selective oxidation of portions of a surface semiconductor layer within a semiconductor-on-insulator substrate, prior to patterning the surface semiconductor layer to form the semiconductor fins that have the multiple heights.

In addition, Yang et al., in “High Performance CMOS Fabricated on Hybrid Substrate With Different Crystallographic Orientation,” IEDM 03, pp. 453-56, teaches a wafer bonding and selective epitaxy method for forming a hybrid orientation substrate that may be used within complimentary metal oxide semiconductor (CMOS) fabrication.

Further, Guo et al., in “FinFET-Based SRAM Design,” ISLPED '05, Aug. 8-10, 2005, San Diego, Calif., pp. 2-7, teaches performance enhancements within both four-transistor and six-transistor SRAM cells may be realized when using finFET transistors, in comparison with bulk silicon metal oxide semiconductor field effect transistors (MOSFETs).

Finally, Kawasaki et al., in “Embedded Bulk FinFET SRAM Cell Technology with Planar FET Peripheral Circuit for hp32 nm node and beyond,” IEEE, 2006 Symp. on VLSI Technology Digest of Technical Papers, 1-4244-0005-8/06, teaches performance characteristics of a bulk finFET SRAM cell with a bulk planar field effect transistor peripheral circuit.

finFET devices and finFET structures are likely to continue to be prominent as semiconductor technology advances. To that end, desirable are additional finFET devices and finFET structures that provide for enhanced performance.

### SUMMARY

The invention provides a finFET structure and a method for fabricating the finFET structure. The finFET structure in accordance with the invention includes multiple semiconductor fins of the same overall height (i.e., overall vertical physical height) over a substrate, but with different vertical channel heights. A method for fabricating such a finFET structure uses a multilayer channel stop/etch stop stack dielectric mask located over a semiconductor substrate and through which is grown a plurality of semiconductor fins. Different vertically stacked layers of the multilayer channel stop/etch stop stack dielectric mask are stripped with respect to different of the semiconductor fins to provide different vertically exposed portions of the semiconductor fins (i.e., different vertical channel heights) that are subsequently fabricated into finFET structures. Thus, within this method at least in-part a channel stop component within a finFET structure is fabricated prior to a semiconductor fin component within the finFET structure. The different vertical channel heights of the semiconductor fins allow for fabrication of finFETs of different performance characteristics, within the same semiconductor substrate.

Notwithstanding the foregoing summary, the invention also contemplates, and thus also does not preclude, a processing sequence that includes: (1) forming multiple semiconductor fins of the same overall vertical physical height over a particular substrate first; and then (2) forming different vertically stacked channel stop layers with respect to different of the semiconductor fins to provide different vertical channel heights of the different semiconductor fins.

A particular finFET structure in accordance with the invention includes a first finFET that includes a first semiconductor fin having a first overall height and a first channel height located over a substrate. This particular finFET structure also includes a second finFET including a second semiconductor fin having a second overall height the same as the first overall height and a second channel height different than the first channel height, also located over the substrate.

A particular method for fabricating a finFET structure in accordance with the invention includes forming over a substrate a first semiconductor fin having a first overall height separated from a second semiconductor fin having a second overall height equal to the first overall height. This particular method also includes forming over the substrate a channel stop layer at a location with respect to one of the first semiconductor fin and the second semiconductor fin, but not at a location with respect to the other of the first semiconductor fin and the second semiconductor fin, to provide a first channel height of the first semiconductor fin different from a second channel height of the second semiconductor fin. This particular method also includes forming a first gate dielectric upon the first semiconductor fin and a second gate dielectric upon the second semiconductor fin. This particular method also includes forming at least one gate electrode upon the first gate dielectric and the second gate dielectric.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, that form a material part of this disclosure, wherein:

FIG. 1 to FIG. 10 show a series of schematic cross-sectional and plan-view diagrams illustrating the results of progressive stages in fabricating a finFET structure in accordance with a preferred embodiment of the invention.

### DESCRIPTION OF THE PREFERRED EMBODIMENT

The invention, which includes a finFET structure and a method for fabricating the finFET structure, is understood within the context of the description provided below. The description provided below is understood within the context of the drawings described above. Since the drawings are intended for illustrative purposes, the drawings are not necessarily drawn to scale.

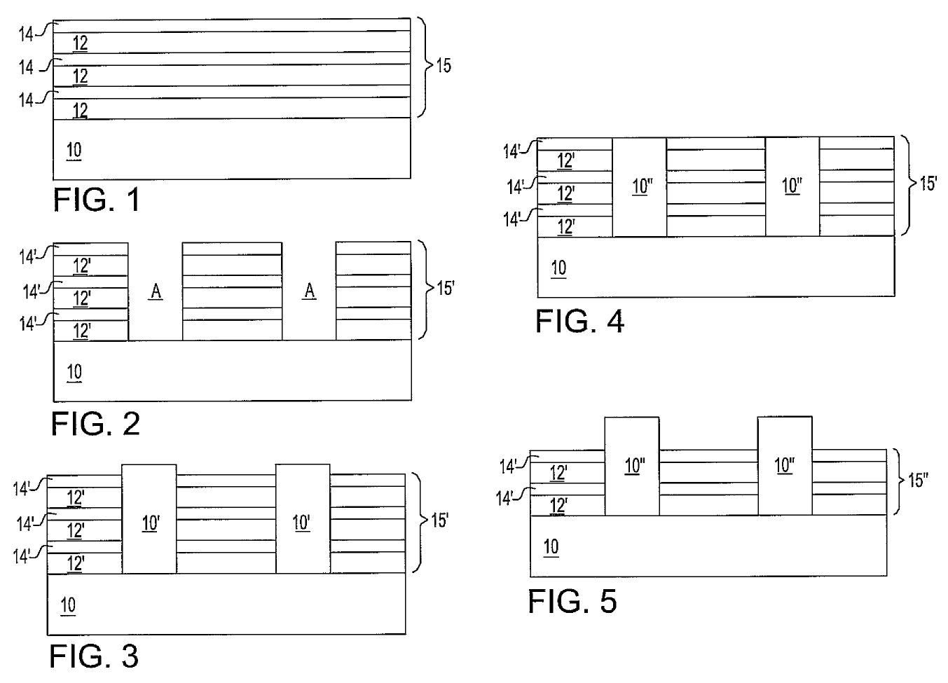

FIG. 1 to FIG. 10 show a series of schematic cross-sectional and plan-view diagrams illustrating the results of progressive stages in fabricating a finFET structure in accordance with a preferred embodiment of the invention.

FIG. 1 shows a semiconductor substrate 10. FIG. 1 also shows successively laminated channel stop layers 12 and etch stop layers 14 located and formed upon or over the semiconductor substrate 10. The successively laminated channel stop layers 12 and etch stop layers 14 in an aggregate comprise a channel stop/etch stop stack 15.

The semiconductor substrate 10 may comprise any of several semiconductor materials. Non-limiting examples include silicon, germanium, silicon-germanium alloy, silicon-carbon alloy, silicon-germanium-carbon alloy and compound (i.e., III-V and II-VI) semiconductor materials. Non-limiting examples of compound semiconductor materials include gallium arsenide, indium arsenide and indium phosphide semiconductor materials.

While the instant embodiment illustrates the invention within the context of a bulk semiconductor substrate for the semiconductor substrate 10, the embodiment is not necessarily intended to be so limited. Rather, under certain circumstances the embodiment and the invention may also be practiced within the context of semiconductor-on-insulator substrates and hybrid orientation substrates. Semiconductor-on-insulator substrates include a base semiconductor substrate that is separated from a surface semiconductor layer by a buried dielectric layer. Hybrid orientation substrates include multiple semiconductor regions of different crystallographic orientation.

The channel stop layers 12 typically comprise a dielectric channel stop material. Non-limiting examples of suitable dielectric channel stop materials include silicon oxide, silicon nitride and silicon oxynitride dielectric channel stop materials. Other dielectric materials are not excluded as suitable channel stop materials. The dielectric channel stop materials may be formed using methods that are otherwise generally conventional in the semiconductor fabrication art. Non-limiting examples include chemical vapor deposition methods (including atomic layer chemical vapor deposition methods) and physical vapor deposition methods (including sputtering methods). Typically, each of the channel stop layers 12 has a thickness from about 200 to about 800 angstroms.

The intervening etch stop layers 14 also typically comprise a dielectric material that may be selected from the same group of dielectric materials from which may be comprised the channel stop layers 12, given the proviso that the etch stop layers 14 and the channel stop layers 12 comprise different materials so that the etch stop layers 14 and the channel stop layers 12 may be effectively etched selectively with respect to each other. As a non-limiting example within the context of the instant embodiment, the channel stop layers 12 may more typically comprise a silicon oxide material while the etch stop layers 14 may more typically comprise a silicon nitride material. Typically each of the etch stop layers 14 has a thickness from about 100 to about 300 angstroms.

FIG. 2 shows the results of etching a plurality of apertures A through the channel stop/etch stop stack 15 to form a channel stop/etch stop stack 15′ that in turn comprises a plurality of channel stop layers 12′ and an intervening plurality of etch stop layers 14′. The foregoing etching may be effected using methods and materials that are otherwise generally conventional in the semiconductor fabrication art. Such methods and materials typically use a mask layer, such as in particular a photoresist mask layer or an electron beam mask layer, that is not otherwise illustrated in FIG. 2, in conjunction with an anisotropic plasma etch method. Such an anisotropic plasma etch method will typically also use a fluorine containing etchant gas composition absent substantial specificity for the etch stop layers 14 with respect to the channel stop layers 12.

FIG. 3 shows a plurality of semiconductor fins 10′ located and formed within, and overflowing, the apertures A that are illustrated in FIG. 2. The semiconductor fins 10′ are formed using an epitaxial method, such as in particular an epitaxial chemical vapor deposition method. Thus, although the semiconductor fins 10′ may comprise different semiconductor materials (i.e., including different base semiconductor materials and dopant materials) from the semiconductor substrate 10, each of the plurality of semiconductor fins 10′ will typically comprise the same crystallographic orientation as the portion of the semiconductor substrate 10 from which it is epitaxially grown.

FIG. 4 shows the results of planarizing the plurality of semiconductor fins 10′ to form a plurality of semiconductor fins 10″. Each of the plurality of semiconductor fins 10″ is planarized with respect to the uppermost etch stop layer 14′, which within the context of the semiconductor structure whose schematic cross-sectional diagram is illustrated in FIG. 4 also comprises a planarizing stop layer. The semiconductor fins 10′ that are illustrated within the schematic cross-sectional diagram of FIG. 3 are planarized to form the semiconductor fins 10″ that are illustrated within the semiconductor structure of FIG. 4 while using a planarizing method that is otherwise generally conventional in the semiconductor fabrication art. Non-limiting examples of such planarizing methods include mechanical planarizing methods and chemical mechanical polish planarizing methods. Chemical mechanical polish planarizing methods are particularly desirable and prevalent.

FIG. 5 shows the results of stripping an uppermost etch stop 14′ and an uppermost channel stop layer 12′ from the semiconductor structure of FIG. 4 to provide a channel stop/etch stop stack 15″ from the channel stop/etch stop stack 15′. The uppermost etch stop layer 14′ and the uppermost channel stop layer 12′ may be stripped using methods and material that are otherwise generally conventional in the semiconductor fabrication art. Included in particular are aqueous phosphoric acid solutions for stripping the uppermost etch stop layer 14′ when comprised of a silicon nitride material and aqueous hydrofluoric acid solutions for stripping the uppermost channel stop layer 12′ when comprised of a silicon oxide material. Other methods and materials combinations are not excluded.

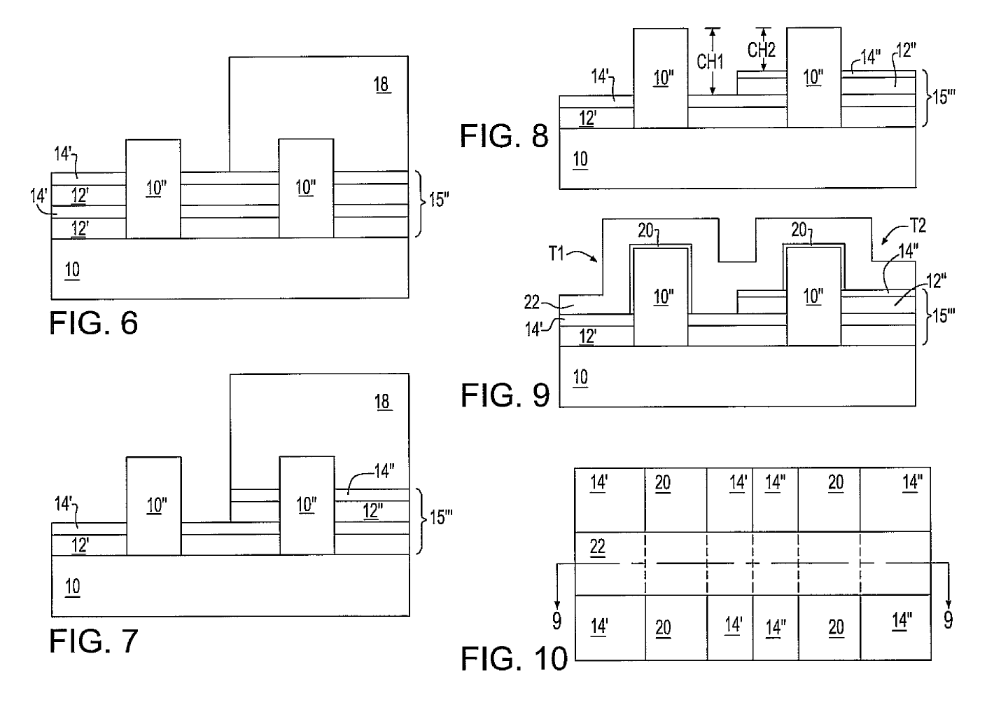

FIG. 6 shows a block mask 18 located and formed upon the right hand side of the semiconductor structure of FIG. 5, including the right hand one of the semiconductor fins 10″. The block mask 18 typically comprises a photoresist material, although other mask materials may also be used for the block mask 18. Positive photoresist materials, negative photoresist materials and hybrid photoresist materials (i.e., providing both positive imaging properties and negative imaging properties) are known for the block mask 18. Typically the block mask 18 comprises a positive photoresist material or a negative photoresist material that has a thickness from about 1200 to about 2500 angstroms.

FIG. 7 shows the results of etching an additional etch stop layer 14′ and an additional channel stop layer 12′ from the left hand side of the semiconductor structure of FIG. 6, but not from the right hand side of the semiconductor structure of FIG. 6, to thus form an asymmetric channel stop/etch stop stack 15′″ that includes in-part an etch stop layer 14″ and a channel stop layer 12″ covering a base of the right band semiconductor fin 10″, but not the left hand semiconductor fin 10″. The foregoing masked etching of the channel stop/etch stop stack 15′ that is illustrated in FIG. 6 to provide the channel stop/etch stop stack 15′″ that is illustrated in FIG. 7 is effected using an anisotropic plasma etch method in conjunction with the block mask 18 as an etch mask, so that a stepped portion of the asymmetric channel stop/etch stop stack 15′″ is provided with a vertical sidewall, or nearly so. The anisotropic plasma etch method preferably uses sequential etchants that each individually have a specificity for the channel stop layer 14′ and then the etch stop layer 12′.

FIG. 8 shows the results of stripping the block mask 18 from the semiconductor structure of FIG. 7. The block mask 18 may be stripped using methods and materials that are otherwise generally conventional in the semiconductor fabrication art. Included in particular are wet chemical stripping methods, dry plasma stripping methods and combinations of wet chemical stripping methods and dry plasma stripping methods.

FIG. 8 also shows a difference in channel height CH1 and CH2 between the left hand semiconductor fin 10″ (i.e., CH1) and the right hand semiconductor fin 10″ (i.e., CH2). Such a difference in the channel height CH1 and the channel height CH2 between the left hand semiconductor fin 10″ and the right hand semiconductor fin 10″ is desirable in certain circumstances, insofar as such a channel height difference within a vertical channel finFET device allows for electrical performance to be tailored within the vertical channel finFET device.

FIG. 9 shows a plurality of gate dielectrics 20 located and formed upon exposed portions of each of the semiconductor fins 10″. The gate dielectrics 20 may comprise conventional dielectric materials such as oxides, nitrides and oxynitrides of silicon that have a dielectric constant from about 4 (i.e., typically a silicon oxide) to about 8 (i.e., typically a silicon nitride), measured in vacuum. Alternatively, the gate dielectrics 20 may comprise generally higher dielectric constant dielectric materials having a dielectric constant from about 8 to at least about 100. Such higher dielectric constant dielectric materials may include, but are not limited to hafnium oxides, hafnium silicates, zirconium oxides, lanthanum oxides, titanium oxides, barium-strontium-titantates (BSTs) and lead-zirconate-titanates (PZTs). The gate dielectrics 20 may be formed using any of several methods that are appropriate to its material of composition. Non-limiting examples include thermal or plasma oxidation or nitridation methods, chemical vapor deposition methods (including atomic layer deposition methods) and physical vapor deposition methods. Typically, the gate dielectrics 20 comprises a thermal silicon oxide dielectric material or a high dielectric constant dielectric material (as discussed above) that has a thickness from about 8 to about 50 angstroms.

FIG. 9 also shows a gate electrode 22 located upon the gate dielectrics 20 and remaining exposed layers and structures within the semiconductor structure of FIG. 8, and also bridging between the semiconductor fins 10″. The gate electrode 22 may comprise materials including but not limited to certain metals, metal alloys, metal nitrides and metal silicides, as well as laminates thereof and composites thereof. The gate electrode 22 may also comprise doped polysilicon and polysilicon-germanium alloy materials (i.e., having a dopant concentration from about 1e18 to about 1e22 dopant atoms per cubic centimeter) and polycide materials (doped polysilicon/metal silicide stack materials). Similarly, the foregoing materials may also be formed using any of several methods. Non-limiting examples include salicide methods, chemical vapor deposition methods and physical vapor deposition methods, such as, but not limited to evaporative methods and sputtering methods. Typically, the gate electrode 22 comprises a doped polysilicon material or a metallic material that has a thickness from about 200 to about 1000 angstroms.

FIG. 10 shows a schematic plan-view diagram that corresponds with the schematic cross-sectional diagram of FIG. 9. FIG. 10 shows the gate electrode 22 that spans the gate dielectrics 20, under which are located the semiconductor fins 10″. Portions of the semiconductor fins 10″ that are covered by the gate electrode 22 comprise channel region portions of the semiconductor fins 10″ which separate source/drain region portions of the semiconductor fins 10″ that are not covered by the gate electrode 22. Also shown in FIG. 10 are the etch stop layer 14′ and the etch stop layer 14″ that in part provide different channel heights for the left hand semiconductor fin 10″ (i.e., CH1) and the right hand semiconductor fin 10″ (i.e., CH2), more specifically illustrated in FIG. 8 and FIG. 9.

FIG. 9 and FIG. 10 show a schematic cross-sectional diagram and a schematic plan-view diagram of a semiconductor structure in accordance with a preferred embodiment of the invention. The semiconductor structure includes a first finFET structure T1 and a second finFET structure T2 located over a substrate which comprises, but need not necessarily be limited to, a semiconductor substrate 10. Each of the first finFET structure T1 and the second finFET structure T2 comprises a semiconductor fin 10″ of equal height over the semiconductor substrate 10 and coplanar over the semiconductor substrate 10. The first finFET structure T1 has a channel height CH1 that is greater than a channel height CH2 of the second finFET structure T2. This difference in channel height derives from the additional channel stop layer 12″ and etch stop layer 14″ located covering the base portion of the semiconductor fin 10″ within the second finFET structure T2 but not the base portion of the semiconductor fin 10″ within first finFET structure T1. The difference in channel height between the first finFET structure T1 and the second finFET structure T2 also allows for differing performance characteristics of the respective finFET devices within the first finFET structure T1 and the second finFET structure T2. Such differing performance characteristics may be desirable, for example and without limitation, within SRAM cells.

The preferred embodiment is illustrative of the invention rather than limiting of the invention. Revisions and modifications may be made to methods, materials, structures and dimensions of a semiconductor structure in accordance with the preferred embodiment, while still providing a semiconductor structure and method for fabrication thereof in accordance with the invention, further in accordance with the accompanying claims.

What is claimed is:

1. A semiconductor structure comprising:
a first finFET comprising a first semiconductor fin having a first overall height and a first channel height located over a substrate; and
a second finFET comprising a second semiconductor fin having a second overall height the same as the first overall height and a second channel height different than the first channel height, also located over the substrate.

2. The semiconductor structure of claim 1 further comprising at least one channel stop layer located adjoining one of the first semiconductor fin and the second semiconductor fin but not adjoining the other of the first semiconductor fin and the second semiconductor fin, the channel stop layer providing the different channel height between the first channel height and the second channel height.

3. The semiconductor structure of claim 1 wherein the first semiconductor fin and the second semiconductor fin are coplanar over the substrate.

4. A method for fabricating a semiconductor structure comprising:
forming over a substrate a first semiconductor fin having a first overall height separated from a second semiconductor fin having a second overall height equal to the first overall height;
forming over the substrate a channel stop layer at a location with respect to one of the first semiconductor fin and the second semiconductor fin, but not at a location with respect to the other of the first semiconductor fin and the second semiconductor fin, to provide a first channel height of the first semiconductor fin different from a second channel height of the second semiconductor fin;
forming a first gate dielectric upon the first semiconductor fin and a second gate dielectric upon the second semiconductor fin; and
forming at least one gate electrode upon the first gate dielectric and the second gate dielectric.

5. The method of claim 4 wherein the first semiconductor fin and the second semiconductor fin are formed simultaneously and coplanar.

6. The method of claim 4 wherein the at least one gate electrode comprises a single gate electrode that spans between the first semiconductor fin and the second semiconductor fin.

7. The method of claim 4 wherein the forming the first semiconductor fin and the forming the second semiconductor fin precedes the forming the channel stop layer.

8. The method of claim 4 wherein the forming the channel stop layer at least in-part precedes the forming the first semiconductor fin and the forming the second semiconductor fin.
